(19) United States
(12) Patent Application Publication
(10) Pub. No.: US 2024/0429159 A1
(43) Pub. Date: Dec. 26, 2024

(54) SEMICONDUCTOR DEVICE

(71) Applicant: Renesas Electronics Corporation, Tokyo (JP)

(72) Inventors: Yasutaka NAKASHIBA, Tokyo (JP); Takayuki IGARASHI, Tokyo (JP)

(21) Appl. No.: 18/666,149

(22) Filed: May 16, 2024

(30) Foreign Application Priority Data
Jun. 22, 2023 (JP) 2023-102527

(51) Int. Cl. H01L 23/522; H01L 23/528; H01L 27/01

(52) U.S. Cl. CPC H01L 23/5227; H01L 23/5283; H01L 27/016; H01L 28/10

(57) ABSTRACT

Providing a semiconductor device that can suppress the heat generation in a transformer. The semiconductor device comprises first, second, third and fourth coils, a lead wire, and an insulating layer. The lead wire is formed on the same layer as the first and second coils. The first and second coils are adjacent to each other through the lead wire in a plan view and are electrically connected in series through the lead wire. The insulating layer covers the first and second coils, and the lead wire. The third coil is formed on the first coil so as to face the first coil through the insulating layer. The fourth coil is formed on the second coil so as to face the second coil through the insulating layer. The third and fourth coils are adjacent to each other in a plan view and are electrically connected to each other.

### CROSS-REFERENCE TO RELATED APPLICATIONS

The disclosure of Japanese Patent Application No. 2023-102527 filed on Jun. 22, 2023, including the specification, drawings and abstract is incorporated herein by reference in its entirety.

### BACKGROUND

The present disclosure relates to a semiconductor device.

International Publication No. WO 2014/097425 (Patent Document 1) describes a semiconductor device. The semiconductor device described in Patent Document 1 has a transformer composed of coils facing each other through an insulating layer. As another semiconductor device having a transformer composed of coils facing each other through the insulating layer, there is a semiconductor device described in Japanese Patent Laid-Open No. 2011-082212 (Patent Document 2).

### SUMMARY

Patent Document 1 and Patent Document 2 merely show examples of transformers where a receiving coil is located on the upper layer of a transmitting coil. Other objects and novel features will become apparent from the description of this specification and the accompanying drawings.

A semiconductor device of this disclosure includes a semiconductor substrate, a first coil, a second coil, a third coil, and a fourth coil, a lead wire, and an insulating layer. The lead wire is formed on the same layer as the first coil and the second coil on the semiconductor substrate. The first coil and the second coil are adjacent to each other through the lead wire in plan view and are electrically connected in series through the lead wire. The insulating layer covers the first coil, the second coil, and the lead wire. The third coil is formed on the first coil so as to face the first coil through the insulating layer. The fourth coil is formed on the second coil so as to face the second coil through the insulating layer. The third coil and the fourth coil are adjacent to each other in plan view and are electrically connected to each other.

According to the semiconductor device of this disclosure, it is possible to suppress the heat generation of the transmitting coil caused by the constant current flowing in the transmitting coil in the transformer where the transmitting coil is located on the upper layer of the receiving coil.

### BRIEF DESCRIPTION OF THE DRAWINGS

FIG. 1 is a block diagram of a semiconductor device DEV1.

FIG. 2 is an explanatory diagram showing an example of a signal transmission from a control circuit CC to a drive circuit DR.

FIG. 3 is the first plan view of a semiconductor chip CHP3.

FIG. 4 is the second plan view of the semiconductor chip CHP3.

FIG. 5 is a cross-sectional view at V-V in FIG. 4.

FIG. 6 is a flow chart for manufacturing the semiconductor chip CHP3.

FIG. 7 is a cross-sectional view explaining a first insulation film forming process S2.

FIG. 8 is a cross-sectional view explaining a wiring forming process S3.

FIG. 9 is a cross-sectional view explaining a second insulation film forming process S4.

FIG. 10 is a cross-sectional view explaining a via plug forming process S5.

FIG. 11 is a cross-sectional view explaining a first coil forming process S6.

FIG. 12 is a cross-sectional view explaining a insulation layer forming process S7.

FIG. 13 is a cross-sectional view explaining a second coil forming process S8.

FIG. 14 is a plan view of a semiconductor chip CHP3 in the semiconductor device DEV2.

FIG. 15 is a plan view of a semiconductor chip CHP3 in the semiconductor device DEV3.

### DETAILED DESCRIPTION

The embodiments of this disclosure will be described with reference to the drawings. In the following drawings, the same or corresponding parts are denoted by the same reference numerals, and redundant description will not be repeated.

### First Embodiment

A semiconductor device according to the first embodiment will be A described. The semiconductor device according to the first embodiment is a semiconductor device DEV1.

### Configuration of the Semiconductor Device DEV1

The configuration of the semiconductor device DEV1 will be described below.

### Outline of the Semiconductor Device DEV1

The outline of the semiconductor device DEV1 will be described below.

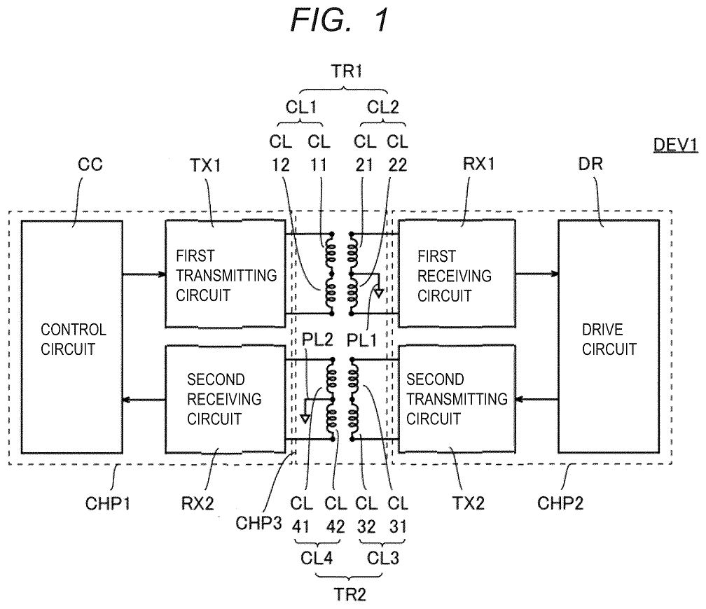

FIG. 1 is a block diagram of the semiconductor device DEV1. As shown in FIG. 1, the semiconductor device DEV1 includes semiconductor chips CHP1, CHP2 and CHP3.

The semiconductor chip CHP1 includes a control circuit CC, a first transmitting circuit TX1, and a second receiving circuit RX2. The semiconductor chip CHP2 includes a drive circuit DR, a first receiving circuit RX1, and a second transmitting circuit TX2. The first transmitting circuit TX1 and the second receiving circuit RX2 are electrically connected to the control circuit CC. The first receiving circuit RX1 and the second transmitting circuit TX2 are electrically connected to the drive circuit DR.

The semiconductor chip CHP3 includes transformers TR1 and TR2, and lead wires PL1 and PL2.

The transformer TR1 includes a transmitting coil CL1 and a receiving coil CL2. The transmitting coil CL1 includes coils CL11 and CL12, and the receiving coil CL2 includes coils CL21 and CL22. The transmitting coil CL1 and the receiving coil CL2 are each electrically connected to the first transmitting circuit TX1 and the first receiving circuit RX1, respectively.

More specifically, one end of the coil CL11 is electrically connected to the first transmitting circuit TX1, the other end of the coil CL11 is electrically connected to one end of the coil CL12, and the other end of the coil CL12 is electrically connected to the first transmitting circuit TX1. Also, one end of the coil CL21 is electrically connected to the first receiving circuit RX1, the other end of the coil CL21 is electrically connected to one end of the coil CL22 through the lead wire PL1, and the other end of the coil CL22 is electrically connected to the first receiving circuit RX1. The lead wire PL1 is connected to a reference potential. The reference potential is, for example, a ground potential.

The transformer TR2 includes a transmitting coil CL3 and a receiving coil CL4. The transmitting coil CL3 includes coils CL31 and CL32, and the receiving coil CL4 includes coils CL41 and CL42. The transmitting coil CL3 and the receiving coil CL4 are each electrically connected to the second transmitting circuit TX2 and the second receiving circuit RX2, respectively.

More specifically, one end of the coil CL31 is electrically connected to the second transmitting circuit TX2, the other end of the coil CL31 is electrically connected to one end of the coil CL32, and the other end of the coil CL32 is electrically connected to the second transmitting circuit TX2. Also, one end of the coil

CL41 is electrically connected to the second receiving circuit RX2, the other end of the coil CL41 is electrically connected to one end of the coil CL42 through the lead wire PL2, and the other end of the coil CL42 is electrically connected to the second receiving circuit RX2. The lead wire PL2 is connected to the reference potential.

In the semiconductor device DEV1, a signal is transmitted from the control circuit CC to the drive circuit DR by the first transmitting circuit TX1, the transformer TR1, and the first receiving circuit RX1. Also, in the semiconductor device DEV1, the signal is transmitted from the drive circuit DR to the control circuit CC by the second transmitting circuit TX2, the transformer TR2, and the second receiving circuit RX2.

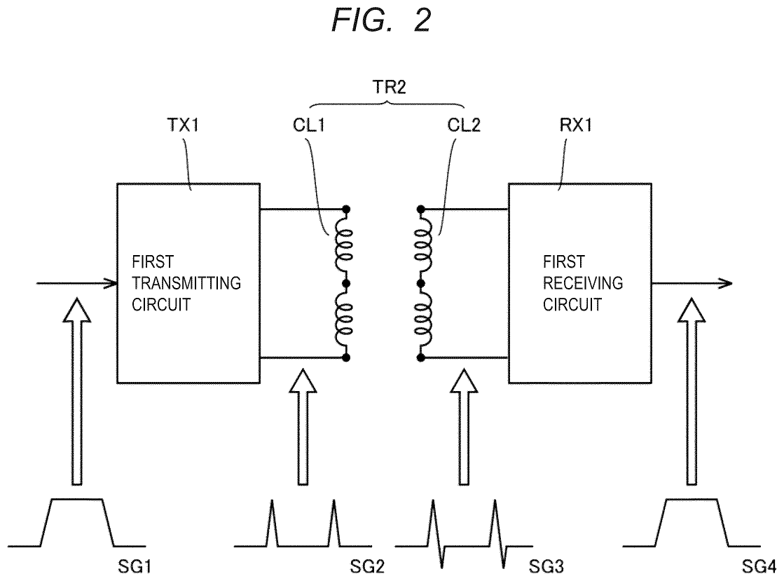

FIG. 2 is an explanatory diagram showing an example of signal transmission from the control circuit CC to the drive circuit DR. As shown in FIG. 2, the control circuit CC inputs a signal SG1 to the first transmitting circuit TX1. The signal SG1 is a square wave. The first transmitting circuit TX1 modulates the signal SG1 to a signal SG2 and sends the signal SG2 to the transmitting coil CL1. When the signal SG2 flows through the transmitting coil CL1, a signal SG3, which corresponds to the signal SG2, flows through the receiving coil CL2 due to induced electromotive force. The first receiving circuit RX1 amplifies the signal SG3 and demodulates it to a signal SG4 (square wave), which is then output to the drive circuit DR. In this way, the signals are transmitted from the control circuit CC to the drive circuit DR. Note that signal transmission from the drive circuit DR to the control circuit CC is also performed in the same way. Thus, in the semiconductor device DEV1, signal transmission between the first transmitting circuit TX1 and the first receiving circuit RX1, and between the second transmitting circuit TX2 and the second receiving circuit RX2, is performed by the pulse communication method.

### Detailed Configuration of the Semiconductor Chip CHP3

The detailed configuration of the semiconductor chip CHP3 will be described below.

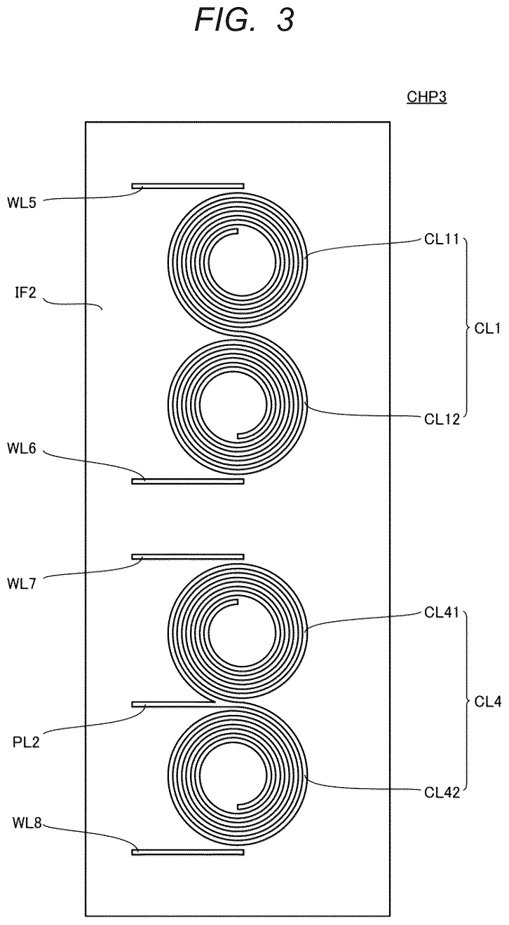

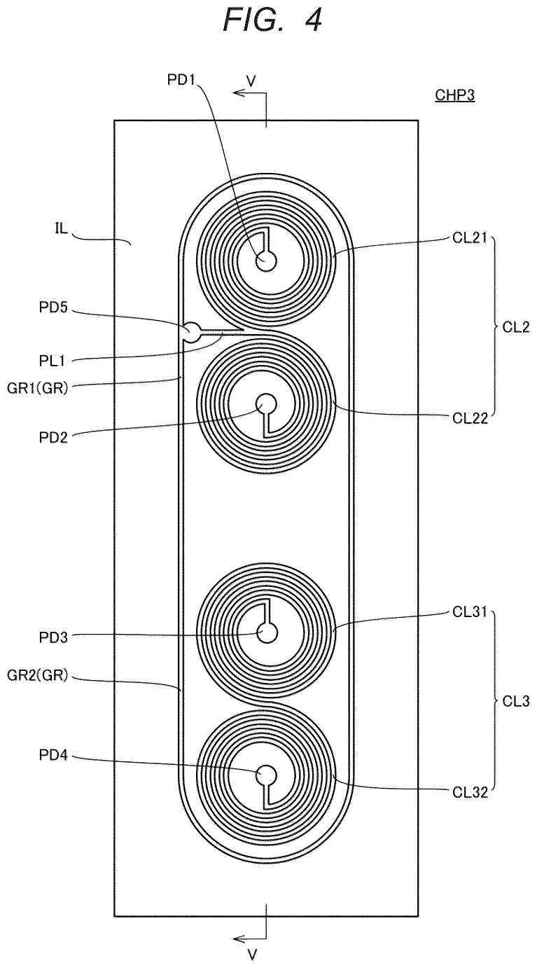

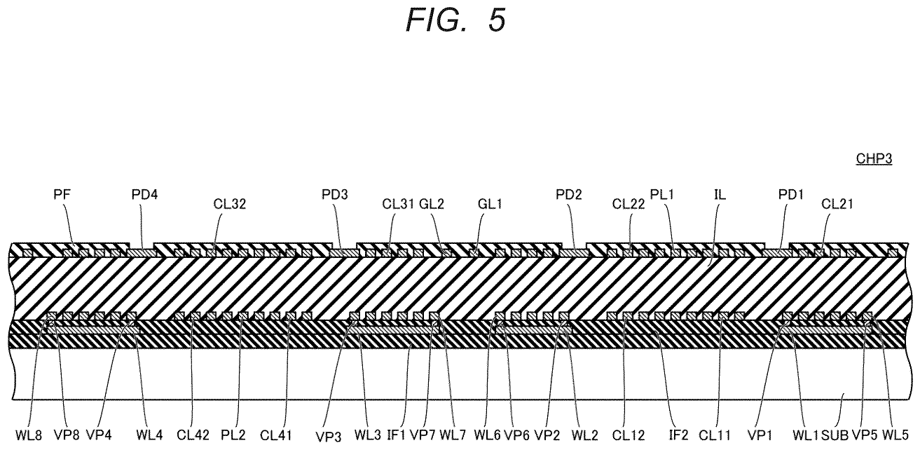

FIG. 3 is a first plan view of the semiconductor chip CHP3. FIG. 4 is a second plan view of the semiconductor chip CHP3. FIG. 5 is a cross-sectional view taken along line V-V in FIG. 4. As shown in FIGS. 3, 4 and 5, the semiconductor chip CHP3 includes a semiconductor substrate SUB, an insulating film IF1, wirings WL1, WL2, WL3 and WL4, an insulating film IF2, via plugs VP1, VP2, VP3, VP4, VP5, VP6, VP7 and VP8, the transmitting coil CL1, the receiving coil CL4, wirings WL5, WL6, WL7 and WL8, the lead wire PL2, an insulating layer IL, the receiving coil CL2, the lead wire PL1, the transmitting coil CL3, electrode pads PD1, PD2, PD3, PD4 and PD5, a guard ring GR, and a passivation film PF.

The material of the semiconductor substrate SUB is, for example, single-crystal silicon. The film insulating IF1 is arranged on the semiconductor substrate SUB. The material of the insulating film IF1 is, for example, silicon oxide. The wirings WL1, WL2, WL3 and WL4 are arranged on the insulating film IF1. The material of the wirings WL1, WL2, WL3 and WL4 is, for example, aluminum or an aluminum alloy. The insulating film IF2 is arranged on the insulating film IF1 so as to cover the wirings WL1, WL2, WL3 and WL4.

The via plugs VP1, VP2, VP3, VP4, VP5, VP6, VP7 and VP8 are embedded in the insulating film IF2. The material of the via plugs VP1, VP2, VP3, VP4, VP5, VP6, VP7 and VP8 is, for example, tungsten.

The transmitting coil CL1 (coils CL11 and CL12), the receiving coil CL4 (coils CL41 and CL42), and the lead wire PL2 are arranged on the insulating film IF2. In other words, the coils CL11, CL12, CL41 and CL42, and the lead wire PL2 are formed on the same layer on the semiconductor substrate SUB. The material of the coils CL11, CL12, CL41 and CL42, and the lead wire PL2 is, for example, aluminum or an aluminum alloy.

The coils CL11 and CL12 are wound in a spiral shape in plan view. The coils CL11 and CL12 are adjacent to each other in plan view. The coils CL11 and CL12 are electrically connected in series. More specifically, the outermost ends of the coils CL11 and CL12 are electrically connected to each other. There are no other lead wires formed on the same layer as the coils CL11, CL12, CL41 and CL42, and the lead wire PL2 between the coils CL11 and CL12. In other words, the coils CL11 and CL12 are directly adjacent to each other in plan view.

The innermost end of the coil CL11 is electrically connected to the wiring WL1 by the via plug VP1. The innermost end of the coil CL12 is electrically connected to the wiring WL2 by the via plug VP2. The end part located at the innermost circumference of the coil CL41 is electrically connected to the wiring WL3 by the via plug VP3. The end part located at the outermost circumference of the coil CL42 is electrically connected to the wiring WL4 by the via plug VP4. The lead wire PL2 is electrically connected to an electrode pad (not shown) located on the insulating layer IL.

The wirings WL5, WL6, WL7 and WL8 are located on the insulating film IF2. The constituent materials of the wirings WL5, WL6, WL7 and WL8 are, for example, aluminum or an aluminum alloy. The wiring WL5 is electrically connected to the wiring WL1 by the via plug VP5, and the wiring WL6 is electrically connected to the wiring WL2 by the via plug VP6. The wiring WL7 is electrically connected to the wiring WL3 by the via plug VP7, and the wiring WL8 is electrically connected to the wiring WL4 by the via plug VP8. The wirings WL5, WL6, WL7 and WL8 are each electrically connected to an electrode pad (not shown) located on the insulating layer IL.

In a plan view, the coil CL11 is wound counterclockwise from the innermost circumference to the outermost circumference. The coil CL12 is wound clockwise from the outermost circumference to the innermost circumference. In other words, the winding direction of the coil CL11 may be opposite to the winding direction of the coil CL12. From another perspective, the coils CL11 and CL12 are in a serial aiding configuration.

The coils CL41 and CL42 are wound in a spiral shape in a plan view. The coils CL41 and CL42 are adjacent to each other in a plan view. The coils CL41 and CL42 are electrically connected in series. More specifically, the end part located at the outermost circumference of the coil CL41 and the end part located at the outermost circumference of the coil CL42 are electrically connected to each other. The lead wire PL2 is formed between the coils CL41 and CL42. From another perspective, the coils CL41 and CL42 are adjacent to each other in a plan view through the lead wire PL2 and are electrically connected in series through the lead wire PL2.

In a plan view, the coil CL41 is wound counterclockwise from the innermost circumference to the outermost circumference. The coil CL42 is wound clockwise from the outermost circumference to the innermost circumference. In other words, the winding direction of the coil CL41 may be opposite to the winding direction of the coil CL42. From another perspective, the coils CL41 and CL42 are in a serial aiding configuration.

The insulating layer IL is arranged on the insulating film IF2 to cover the coils CL11, CL12, CL41 and CL42, the lead wire PL2, the wirings WL5, WL6, WL7 and WL8. Although not shown, the insulating layer IL may be formed by stacking a plurality of insulating films. The constituent materials of each insulating film forming the insulating layer IL are, for example, silicon oxide.

The receiving coil CL2 (coils CL21 and CL22), the transmitting coil CL3 (coils CL31, CL32), and the lead wire PL1 are arranged on the insulating layer IL. The constituent materials of the coils CL21, CL22, CL31 and CL32, and the lead wire PL1 are, for example, aluminum or an aluminum alloy.

The coils CL21 and CL22 are opposed to the coils CL11 and CL12, respectively, through the insulating layer IL. From another perspective, in a plan view, the coils CL21 and CL22 overlap with the coils CL11 and CL12. From yet another perspective, the coils CL21 and CL22 are magnetically coupled to the coils CL11 and CL12, respectively. As described above, since the coils CL21 and CL22 are on the insulating layer IL, the coils CL21 and CL22 are arranged on the coils CL11 and CL12, respectively, through the insulating layer IL.

The coils CL21 and CL22 are wound in a spiral shape when viewed in a plan view. The coils CL21 and CL22 are adjacent to each other in a plan view. The coils CL21 and CL22 are electrically connected in series. More specifically, the ends at the outermost periphery of the coils CL21 and CL22 are electrically connected to each other. The lead wire PL1 is formed between the coils CL21 and CL22. In other words, the coils CL21 and CL22 are adjacent to each other in a plan view through the lead wire PL1, and are electrically connected in series through the lead wire PL1.

The coil CL21 is wound counterclockwise from the innermost periphery to the outermost periphery in a plan view. The coil CL22 is wound clockwise from the outermost periphery to the innermost periphery in a plan view. That is, the winding direction of the coil CL21 may be opposite to the winding direction of the coil CL22. In other words, the coils CL21 and CL22 are in a series aiding configuration.

The coils CL31 and CL32 are facing the coils CL41 and CL42, respectively, through the insulating layer IL. In other words, in a plan view, the coils CL31 and CL32 overlap with the coils CL41 and CL42. From another perspective, the coils CL31 and CL32 are magnetically coupled with the coils CL41 and CL42, respectively. As mentioned above, since the coils CL31 and CL32 are on the insulating layer IL, the coils CL31 and CL32 are arranged on the coils CL41 and CL42, respectively, through the insulating layer IL.

The coils CL31 and CL32 are wound in a spiral shape when viewed in a plan view. The coils CL31 and CL32 are adjacent to each other in a plan view. The coils CL31 and CL32 are electrically connected in series. More specifically, the ends at the outermost periphery of the coils CL31 and CL32 are electrically connected to each other. There are no other lead wires formed at the same layer as the coils CL21, CL22, CL31 and CL32, and the lead wire PL1 between the coils CL31 and CL32. In other words, in a plan view, the coils CL31 and CL32 are directly adjacent to each other.

The coil CL31 is wound counterclockwise from the innermost periphery to the outermost periphery in a plan view. The coil CL32 is wound clockwise from the outermost periphery to the innermost periphery in a plan view. That is, the winding direction of the coil CL31 may be opposite to the winding direction of the coil CL32. In other words, the coils CL31 and CL32 are in a series aiding configuration.

The distance between the coil CL11 and the coil CL21 or between the coil CL12 and the coil CL22 is, for example, 6 micrometers or more and 10 micrometers or less. The distance between the coil CL11 and the coil CL21 or between the coil CL12 and the coil CL22 may be 10 micrometers or more and 14 micrometers or less. The distance between the coil CL41 and the coil CL31 or between the coil CL42 and the coil CL32 is, for example, 6micrometers or more and 10 micrometers or less. The distance between the coil CL41 and the coil CL31 or between the coil CL42 and the coil CL32 may be 10 micrometers or more and 14 micrometers or less.

The electrode pads PD1, PD2, PD3, PD4 and PD5 are arranged on the insulating layer IL. The material of the electrode pads PD1, PD2, PD3, PD4 and PD5 is, for example, aluminum or an aluminum alloy. The electrode pad PD1 is connected to the end of the innermost periphery of the coil CL21. The electrode pad PD2 is connected to the end of the innermost periphery of the coil CL22. The electrode pad PD3 is connected to the end of the innermost periphery of the coil CL31. The electrode pad PD4 is connected to the end of the innermost periphery of the coil CL32. The electrode pad PD5 is connected to the end of the lead wire PL1 on the opposite side of the coils CL21 and CL22.

The guard ring GR is arranged on the insulating layer IL. The guard ring GR has a first portion GR1 and a second portion GR2. The first portion GR1 surrounds the receiving coil CL2 in a plan view. The second portion GR2 surrounds the transmitting coil CL3 in a plan view. The electrode pad PD5 is in contact with the guard ring GR (first portion GR1). Therefore, the guard ring GR is connected to the reference potential in the same way as the lead wire PL1. The material of the guard ring GR is, for example, aluminum or an aluminum alloy.

The passivation film PF is arranged on the insulating layer IL to cover the receiving coil CL2 (coils CL21 and CL22), the transmitting coil CL3 (coils CL31 and CL32), the lead wire PL1, the electrode pads PD1, PD2, PD3, PD4 and PD5, and the guard ring GR. The electrode pads PD1, PD2, PD3, PD4 and PD5 are exposed from an opening of the passivation film PF. The material of the passivation film PF is, for example, silicon nitride.

### Manufacturing Method of the Semiconductor Chip CHP3

Hereinafter, the manufacturing method of the semiconductor chip CHP3 will be explained.

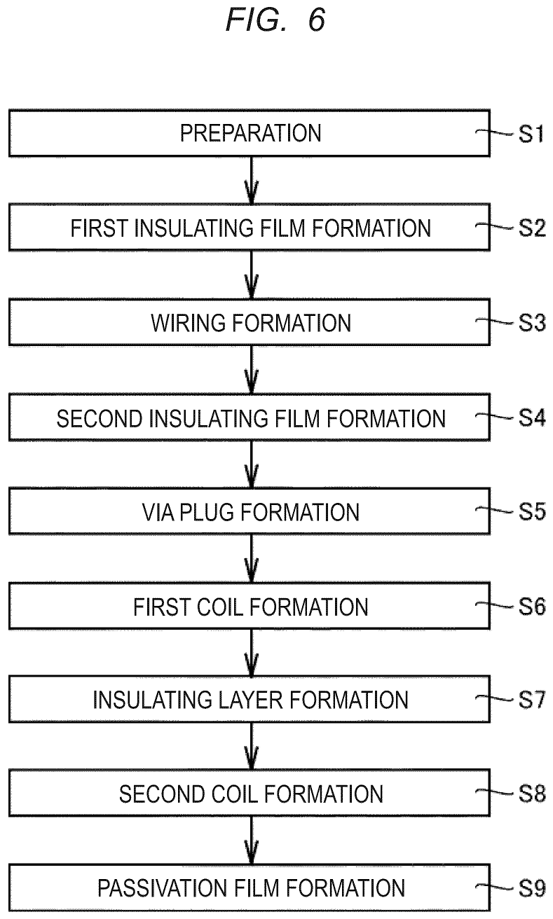

FIG. 6 is a flow chart for manufacturing the semiconductor chip CHP3. As shown in FIG. 6, the manufacturing method of the semiconductor chip CHP3 includes a preparation step S1, a first insulating film formation step S2, a wiring formation step S3, a second insulating film formation step S4, a via plug formation step S5, a first coil formation step S6, an insulating layer formation step S7, a second coil formation step S8, and a passivation film formation step S9.

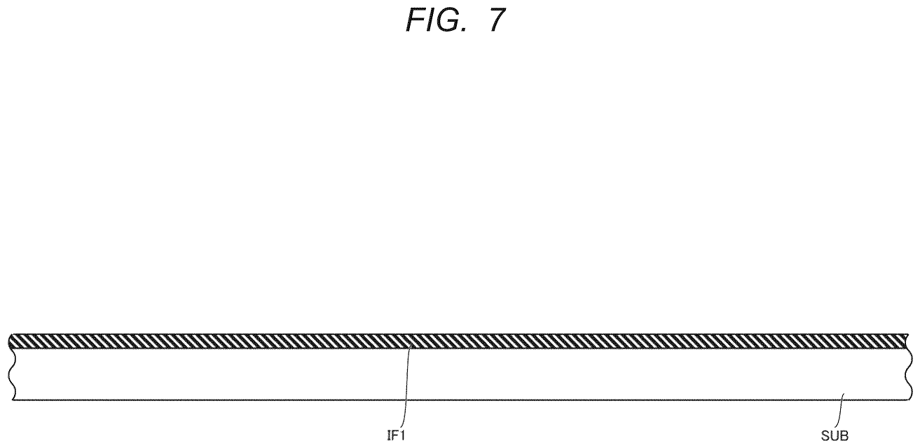

In the preparation step S1, the semiconductor substrate SUB is prepared. After the preparation step S1, the first insulating film formation step S2 is performed. FIG. 7 is a cross-sectional view explaining the first insulating film formation step S2. As shown in FIG. 7, in the first insulating film formation step S2, an insulating film IF1 is formed on the semiconductor substrate SUB by, for example, a CVD (Chemical Vapor Deposition) method. After the first insulating film formation step S2, the wiring formation step S3 is performed.

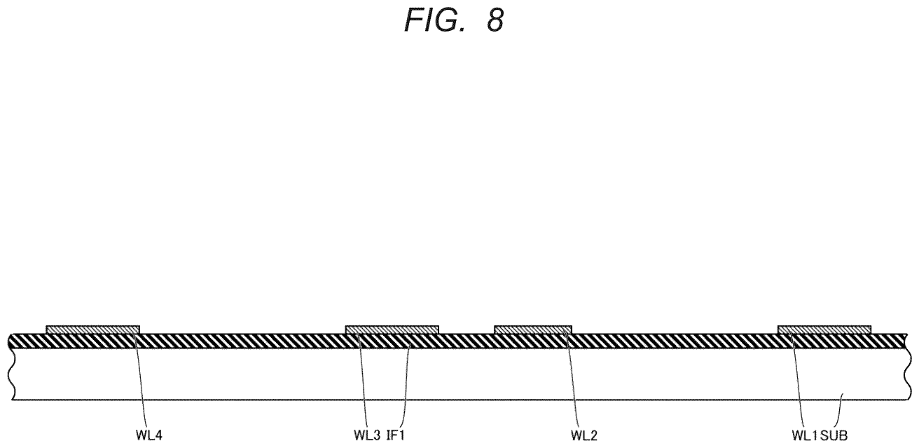

FIG. 8 is a cross-sectional view explaining the wiring formation step S3. As shown in FIG. 8, in the wiring formation step S3, the wirings WL1, WL2, WL3 and WL4 are formed on the insulating film IF1. In the wiring formation step S3, first, the constituent materials of the wirings WL1, WL2, WL3 and WL4 are deposited by, for example, a sputtering method. Second, the deposited constituent materials of the wirings WL1, WL2, WL3 and WL4 are patterned by dry etching using a resist pattern formed by photolithography as a mask. After the wiring formation step S3, the second insulating film formation step S4 is performed.

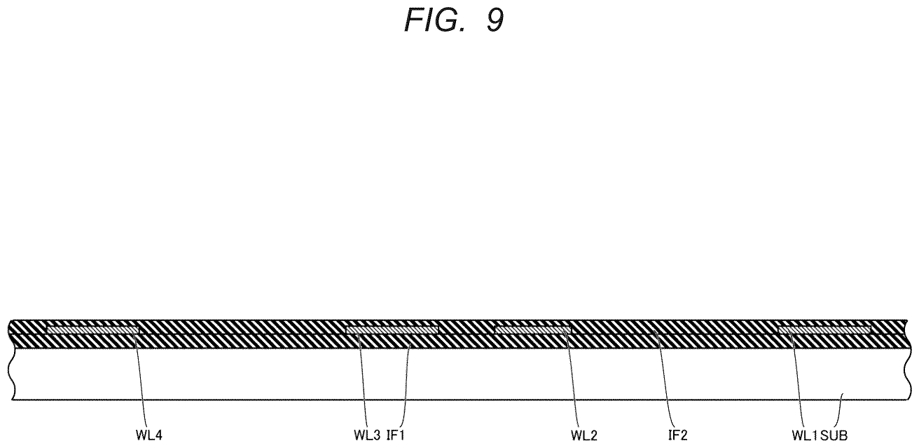

FIG. 9 is a cross-sectional view explaining the second insulating film formation step S4. In the second insulating film formation step S4, as shown in FIG. 9, the insulating film IF2 is formed on the insulating film IF1 so as to cover the wirings WL1, WL2, WL3 and WL4. In the second insulating film formation step S4, first, the constituent materials of the insulating film IF2 are deposited by, for example, a CVD method. Second, the deposited constituent materials of the insulating film IF2 are planarized by, for example, a CMP (Chemical Mechanical Polishing) method. After the second insulating film formation step S4, the via plug formation step S5 is performed.

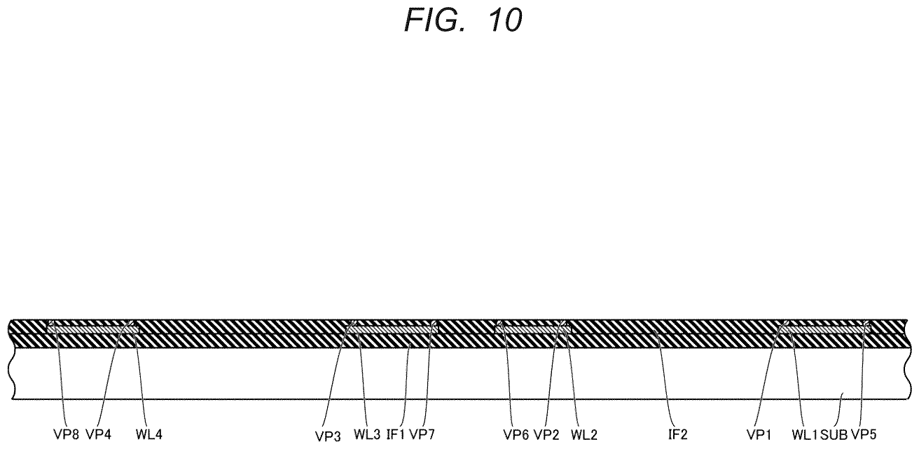

FIG. 10 is a cross-sectional view explaining the via plug formation step S5. As shown in FIG. 10, in the via plug formation step S5, the via plugs VP1, VP2, VP3, VP4, VP5, VP6, VP7 and VP8 are embedded in the insulating film IF2. In the via plug formation step S5, first, via holes are formed in the insulating film IF2 by dry etching using a resist pattern formed by photolithography as a mask. Second, the constituent materials of the via plugs VP1, VP2, VP3, VP4, VP5, VP6, VP7 and VP8 are embedded in the via holes by, for example, a CVD method.

Third, the constituent materials of the via plugs VP1, VP2, VP3, VP4, VP5, VP6, VP7 and VP8 that protrude from the via holes are removed by, for example, a CMP method. After the via plug formation step S5, the first coil formation step S6 is performed.

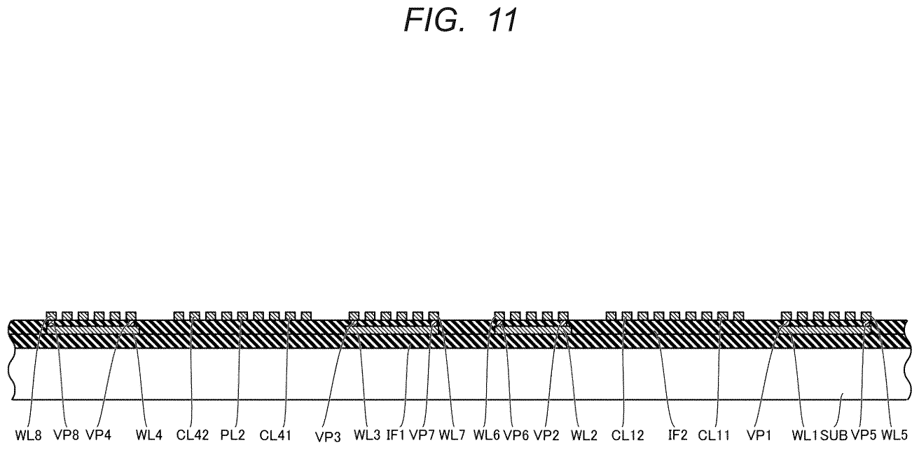

FIG. 11 is a cross-sectional view explaining the first coil formation step S6. As shown in FIG. 11, in the first coil formation step S6, the transmitting coil CL1, the receiving coil CL4, the lead wire PL2, and the wirings WL5, WL6, WL7 and WL8 are formed on the insulating film IF2. In the first coil formation step S6, first, the constituent materials of the transmitting coil CL1, the receiving coil CL4, the lead wire PL2, and the wirings WL5, WL6, WL7 and WL8 are deposited by, for example, sputtering. Secondly, the constituent materials of the formed the transmitting coil CL1, the receiving coil CL4, the lead wire PL2, the wirings WL5, WL6,

WL7 and WL8 are patterned by dry etching using a resist pattern formed by photolithography, for example, as a mask. After the first coil forming step S6, the insulating layer forming step S7 is performed.

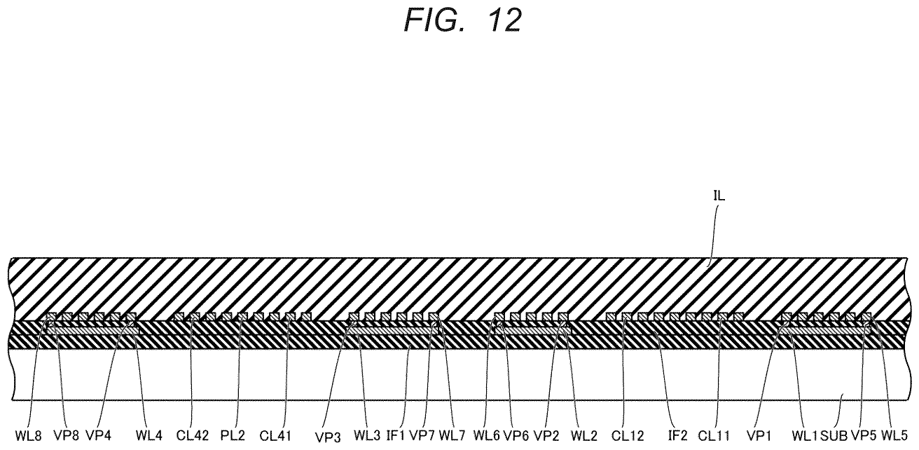

FIG. 12 is a cross-sectional view explaining the insulating layer forming step S7. In the insulating layer forming step S7, as shown in FIG. 12, the insulating layer IL is s formed on the insulating film IF2 so as to cover the transmitting coil CL1, the receiving coil CL4, the lead wire PL2, the wirings WL5, WL6, WL7 and WL8. The insulating layer IL is formed by repeating the same process as the second insulating film forming step S4. After the insulating layer forming step S7, the second coil forming step S8 is performed.

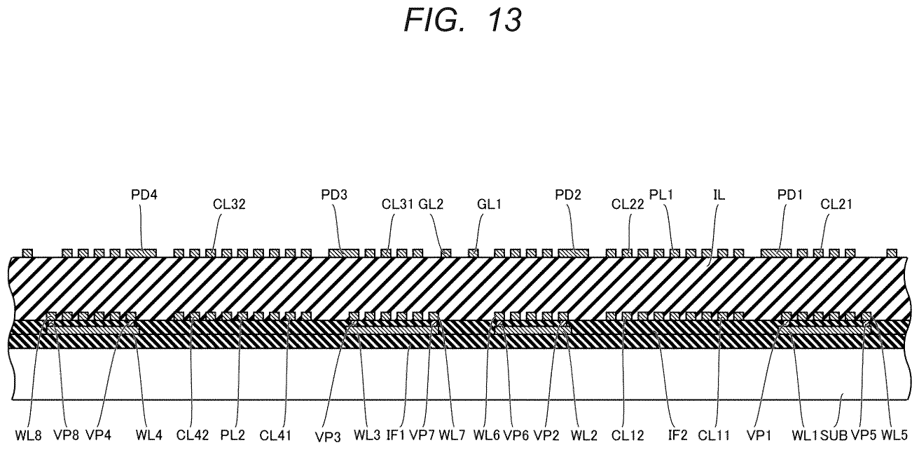

FIG. 13 is a cross-sectional view explaining the second coil forming step S8. As shown in FIG. 11, in the second coil forming step S8, the receiving coil CL2, the transmitting coil CL3, the lead wire PL1, the electrode pads PD1, PD2, PD3, PD4 and PD5, and the guard ring GR are formed on the insulating layer IL. In the second coil forming step S8, firstly, the constituent materials of the receiving coil CL2, the transmitting coil CL3, the lead wire PL1, the electrode pads PD1, PD2, PD3, PD4 and PD5, and the guard ring GR are formed by sputtering, for example. Secondly, the constituent materials of the formed the receiving coil CL2, the transmitting coil CL3, the lead wire PL1, the electrode pads PD1, PD2, PD3, PD4 and PD5, and the guard ring GR are patterned by dry etching using a resist pattern formed by photolithography, for example, as a mask. After the second coil forming step S8, the passivation film forming step S9 is performed.

In the passivation film forming step S9, the passivation film PF is formed on the insulating layer IL so as to cover the receiving coil CL2, the transmitting coil CL3, the lead wire PL1, the electrode pads PD1, PD2, PD3, PD4 and PD5, and the guard ring GR. In the passivation film forming step S9, firstly, the constituent materials of the passivation film PF are formed by CVD method, for example. Secondly, the constituent materials of the passivation film PF are patterned by dry etching using a resist pattern formed by photolithography, for example, as a mask. As a result, the structure of the semiconductor chip CHP3 shown in FIGS. 3 to 5 is formed.

### Effect of the Semiconductor Device DEV1

The effect of the semiconductor device DEV1 will be explained below.

In the semiconductor device DEV1, the transformers TR1 and TR2 are consolidated in the semiconductor chip CHP3. Since no semiconductor elements such as transistors are formed in the semiconductor chip CHP3, it is possible to optimize the manufacturing process of the semiconductor chip CHP3 according to the transformers TR1 and TR2.

In the semiconductor device DEV1, no lead wire is formed between the coil CL11 and the coil CL12. Also, in the semiconductor device DEV1, no lead wire is formed between the coil CL31 and the coil CL32. Therefore, a constant current does not flow in the coils CL11, CL12, CL31 and CL32 (current flows only during transmission). Therefore, according to the semiconductor device DEV1, it is possible to suppress the heat generation of the semiconductor chip CHP3. As a result of suppressing the heat generation of the semiconductor chip CHP3, it is also possible to suppress the occurrence of electromigration in the coils CL11, CL12, CL31, and CL32.

In the semiconductor device DEV1, the lead wire PL1 is formed between the coil CL21 and the coil CL22, and the lead wire PL2 is formed between the coil CL41 and the coil CL42. Then, the lead wires PL1 and PL2 are connected to the reference potential. Therefore, in the semiconductor device DEV1, it is possible to stabilize the potential at the connection part between the coil CL21 and the coil CL22 and the connection part between the coil CL41 and the coil CL42. In the semiconductor device DEV1, it is possible to suppress common mode noise by configuring the coils CL11 and CL12 (coils CL31 and CL32) in a series-aiding configuration.

### Second Embodiment

A semiconductor device according to the second embodiment will be described. The semiconductor device according to the second embodiment is defined as a semiconductor device DEV2. Here, differences from the semiconductor device DEV1 will be mainly described, and redundant description will not be repeated.

### Configuration of the Semiconductor Device DEV2

The configuration of the semiconductor device DEV2 will be described below.

The semiconductor device DEV2 has a semiconductor chip CHP1, a semiconductor chip CHP2, and a semiconductor chip CHP3. In this respect, the configuration of the semiconductor device DEV2 is common to the configuration of the semiconductor device DEV1.

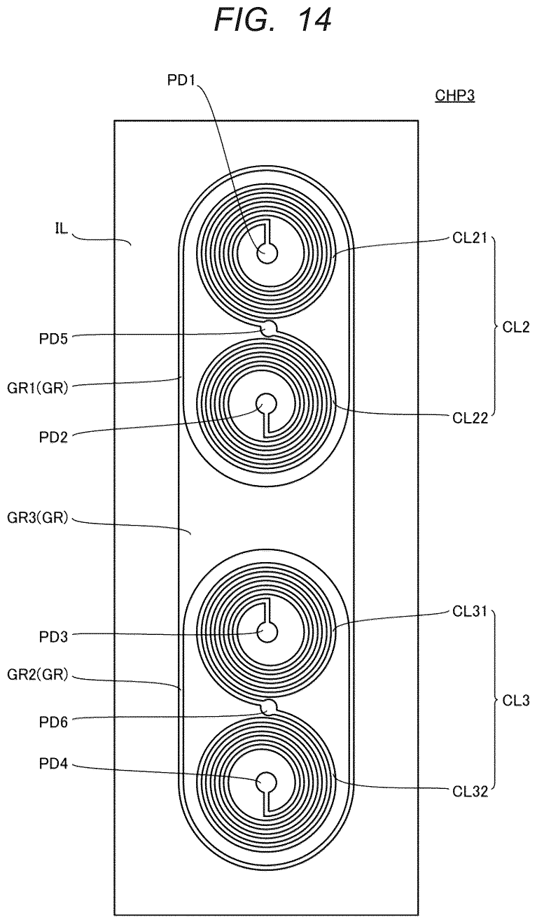

FIG. 14 is a plan view of the semiconductor chip CHP3 in the semiconductor device DEV2. As shown in FIG. 14, in the semiconductor device DEV2, the semiconductor chip CHP3 does not have the lead wire PL1. Instead, in the semiconductor device DEV2, coils CL21 and CL22 are adjacent to each other through an electrode pad PD5 in a plan view, and are electrically connected in series through the electrode pad PD5.

Also, the semiconductor device DEV2 has an electrode pad PD6 on the semiconductor chip CHP3. The electrode pad PD6 is arranged on an insulating layer IL. The material of the electrode pad PD6 is, for example, aluminum or an aluminum alloy. In the semiconductor device DEV2, coils CL31 and CL32 are adjacent to each other through the electrode pad PD6 in a plan view, and are electrically connected in series through the electrode pad PD6. However, since the electrode pad PD6 is not connected to a reference potential, the electrode pad PD6 is not exposed from a passivation film PF.

In the semiconductor device DEV2, as a result of the electrode pad PD2 being formed between the coils CL21 and CL22, the electrode pad PD5 is separated from the guard ring GR (first portion GR1). In the semiconductor device DEV2, the guard ring GR further has a connecting portion GR3 connecting the first portion GR1 and the second portion GR2. Although not shown, in the semiconductor device DEV2, the guard ring GR is supplied with the reference potential because the connecting portion GR3 is exposed from the passivation film PF. In these respects, the configuration of the semiconductor device DEV2 is different from the configuration of the semiconductor device DEV1.

### Effect of the Semiconductor Device DEV2

The effect of the semiconductor device DEV2 will be described below.

In the semiconductor device DEV1, the electrode pad PD5 and the guard ring GR (first portion GR1) are in contact, and this contact portion becomes a singularity that causes a decrease in breakdown voltage due to electric field concentration. However, in the semiconductor device DEV2, since the electrode pad PD5 is separated from the guard ring GR (first portion GR1), such a singularity does not occur, and it is possible to secure the breakdown voltage of the semiconductor chip CHP3.

### Third Embodiment

A semiconductor device according to the third embodiment will be described. The semiconductor device according to the second embodiment is defined as a semiconductor device DEV3. Here, differences from the semiconductor device DEV2 will be mainly described, and redundant description will not be repeated.

### Configuration of the Semiconductor Device DEV3

The configuration of the semiconductor device DEV3 will be described below.

The semiconductor device DEV3 has a semiconductor chip CHP1, a semiconductor chip CHP2, and a semiconductor chip CHP3. In this respect, the configuration of the semiconductor device DEV3 is common to the configuration of the semiconductor device DEV2.

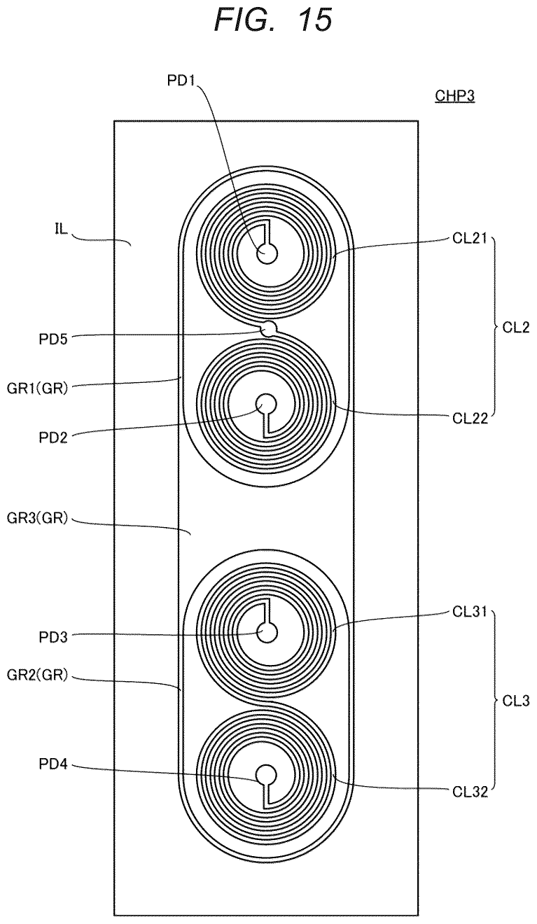

FIG. 15 is a plan view of the semiconductor chip CHP3 in the semiconductor device DEV3. As shown in FIG. 15, in the semiconductor device DEV3, the semiconductor chip CHP3 does not have an electrode pad PD6. In other words, in the semiconductor device DEV3, in a plan view, the shape of a receiving coil CL2 is different from the shape of a transmitting coil CL3. In this respect, the configuration of the semiconductor device DEV3 is different from the configuration of the semiconductor device DEV2.

### Effect of the Semiconductor Device DEV3

The effect of the semiconductor device DEV3 will be described below.

In the semiconductor device DEV3, the width of the transmitting coil CL3 becomes smaller compared to the semiconductor device DEV2, because the electrode pad PD6 is not formed. Therefore, according to the semiconductor device DEV3, it becomes possible to reduce the layout of the transmitting coil CL3.

### APPENDIXES

The above embodiments include the following configurations.

### Appendix 1

A semiconductor device comprising:
a first semiconductor chip;
a second semiconductor chip; and
a third semiconductor chip, wherein
the first semiconductor chip has a first receiving circuit,
the second semiconductor chip has a first transmitting circuit,
the third semiconductor chip has a first receiving coil electrically connected to the first receiving circuit, a first transmitting coil electrically connected to the first transmitting circuit, a first lead wiring, and an insulating layer,
the first receiving coil has a first coil and a second coil,
the first transmitting coil has a third coil and a fourth coil,
the first lead wiring is formed on a same layer as the first coil and the second coil,
the first coil and the second coil are adjacent to each other across the first lead wiring in a plan view and are electrically connected in series via the first lead wiring,
the insulating layer covers the first coil, the second coil, and the first lead wiring,
the third coil is formed such that the third coil faces to the first coil through the insulating layer,
the fourth coil is formed such that the fourth coil faces to the second coil through the insulating layer,
the third coil and the fourth coil are adjacent to each other in a plan view and are electrically connected to each other.
the first transmitting circuit transmits a signal to the first receiving circuit via the first transmitting coil and the first receiving coil.

### Appendix 2

The semiconductor device according to Appendix 1, wherein
in cross-sectional view, a distance between the first coil and the third coil or a distance between the second coil and the fourth coil is 6 micrometers or more and 10 micrometers or less.

### Appendix 3

3. The semiconductor device according to Appendix 1, wherein
   in cross-sectional view, a distance between the first coil and the third coil or a distance between the second coil and the fourth coil is 10 micrometers or more and 14 micrometers or less.

### Appendix 4

The semiconductor device according to Appendix 1, wherein
the first coil and the third coil are overlapped each other in plan view, and
the second coil and the fourth coil are overlapped each other in plan view.

### Appendix 5

The semiconductor device according to Appendix 1, wherein
the first coil and the third coil are magnetically coupled to each other, and
the second coil and the fourth coil are magnetically coupled to each other.

### Appendix 6

The semiconductor device according to Appendix 1, wherein
the first lead wiring is connected to a reference potential.

### Appendix 7

The semiconductor device according to Appendix 1, wherein
a lead wiring is not formed in the same layer as the third coil and the fourth coil between the third coil and the fourth coil, and
the third coil and the fourth coil are directly adjacent to each other in plan view.

### Appendix 8

A semiconductor device according to Appendix 1 further comprising:
the first semiconductor chip has a second receiving circuit,
the second semiconductor chip has a second transmitting circuit,
the third semiconductor chip has a second transmitting coil connected to the second transmitting circuit, a second receiving coil connected to the second receiving circuit, a second lead wiring,
the second transmitting coil has a fifth coil and a sixth coil,
the second receiving coil has a seventh coil and an eighth coil,
the insulating layer covers the fifth coil and the sixth coil,
the seventh coil is formed such that the seventh coil faces to the fifth coil through the insulating layer,
the eighth coil is formed such that the eighth coil faces to the sixth coil through the insulating layer,
the seventh coil and the eighth coil are adjacent to each other across the second lead wiring in a plan view and are electrically connected in series via the second lead wiring,
the second transmitting circuit transmits a signal to the second receiving circuit via the second transmitting coil and the second receiving coil.

What is claimed is:

1. A semiconductor device comprising:
first, second, third and fourth coils;
a lead wiring; and
an insulating layer, wherein
the lead wiring is formed on a same layer as the first coil and the second coil,
the first coil and the second coil are adjacent to each other the lead wiring in a plan view and are electrically connected in series via the lead wiring,
the insulating layer covers the first coil, the second coil, and the lead wiring,
the third coil is formed such that the third coil faces to the first coil through the insulating layer,
the fourth coil is formed such that the fourth coil faces to the second coil through the insulating layer,
the third coil and the fourth coil are adjacent to each other in a plan view and are electrically connected to each other.

2. The semiconductor device according to claim 1, wherein
in cross-sectional view, a distance between the first coil and the third coil or a distance between the second coil and the fourth coil is 6 micrometers or more and 10 micrometers or less.

3. The semiconductor device according to claim 1, wherein
in cross-sectional view, a distance between the first coil and the third coil or a distance between the second coil and the fourth coil is 10 micrometers or more and 14 micrometers or less.

4. The semiconductor device according to claim 1, wherein
the first coil and the third coil are overlapped each other in plan view, and
the second coil and the fourth coil are overlapped each other in plan view.

5. The semiconductor device according to claim 1, wherein
the first coil and the third coil are magnetically coupled to each other, and
the second coil and the fourth coil are magnetically coupled to each other.

6. The semiconductor device according to claim 1, wherein
the lead wiring is connected to a reference potential.

7. The semiconductor device according to claim 1, wherein
a lead wiring is not formed in the same layer as the third coil and the fourth coil between the third coil and the fourth coil, and
the third coil and the fourth coil are directly adjacent to each other in plan view.

8. A semiconductor device comprising:
first, second, third, fourth, fifth, sixth, seventh and eighth coils;
first and second lead wirings; and
an insulating layer, wherein
the first lead wiring is formed on a same layer as the first coil, the second coil, the third coil and the fourth coil,
the first coil and the second coil are adjacent to each other across the first lead wiring in a plan view and are electrically connected in series via the first lead wiring,
the third coil and the fourth coil are adjacent to each other in a plan view and are electrically connected in series,
the insulating layer covers the first coil, the second coil, the third coil, the fourth coil and the first lead wiring,
the fifth coil is formed such that the fifth coil faces to the first coil through the insulating layer,
the sixth coil is formed such that the sixth coil faces to the second coil through the insulating layer,
the seventh coil is formed such that the seventh coil faces to the third coil through the insulating layer,
the eighth coil is formed such that the eighth coil faces to the fourth coil through the insulating layer,
the fifth coil and the sixth coil are adjacent to each other in a plan view and are electrically connected in series,
the seventh coil and the eighth coil are adjacent to each other across the second lead wiring in a plan view and are electrically connected in series via the second lead wiring.

9. The semiconductor device according to claim 8, wherein
a lead wiring is not formed in the same layer as the first coil, the second coil, the third coil and the fourth coil between the third coil and the fourth coil,
the third coil and the fourth coil are directly adjacent to each other in plan view,
a lead wiring is not formed in the same layer as the fifth coil, the sixth coil, the seventh coil and the eighth coil between the fifth coil and the sixth coil, and
the fifth coil and the sixth coil are directly adjacent to each other in plan view.

10. A semiconductor device comprising:
first, second, third, fourth, fifth, sixth, seventh and eighth coils;
a lead wiring;
first, second, third, fourth, fifth electrode pad; and
an insulating layer, wherein
the lead wiring is formed on a same layer as the first coil, the second coil, the third coil and the fourth coil,
the first coil and the second coil are adjacent to each other across the lead wiring in a plan view and are electrically connected in series via the lead wiring,
the third coil and the fourth coil are adjacent to each other in a plan view and are electrically connected in series,
the insulating layer covers the first coil, the second coil, the third coil, the fourth coil and the lead wiring,
the fifth coil is formed such that the fifth coil faces to the first coil through the insulating layer,
the sixth coil is formed such that the sixth coil faces to the second coil through the insulating layer,
the seventh coil is formed such that the seventh coil faces to the third coil through the insulating layer,
the eighth coil is formed such that the eighth coil faces to the fourth coil through the insulating layer,
the first, second, third and fourth electrode pads are electrically connected to the innermost periphery of the fifth, sixth, seventh and eighth coils respectively,
the fifth coil and the sixth coil are adjacent to each other in plan view, and are electrically connected,
the seventh coil and the eighth coil are adjacent to each other across the fifth electrode pad in a plan view and are electrically connected in series via the fifth electrode pad.

11. The semiconductor device according to claim 10 further comprising:
a sixth electrode pad, and
a passivation film, wherein
the fifth coil and the sixth coil are adjacent to each other across the sixth electrode pad in a plan view and are electrically connected in series via the sixth electrode pad,
the passivation film covers the fifth, sixth, seventh coil and eighth coils and the first, second, third, fourth, fifth and sixth electrode pads, and
an opening is formed in the passivation film such that the fifth electrode pad is exposed, and
an opening is not formed in the passivation film such that the sixth electrode pad is exposed.

12. The semiconductor device according to claim 10, wherein
in cross-sectional view, a distance between the first coil and the fifth coil or a distance between the second coil and the sixth coil is 6 micrometers or more and 10 micrometers or less.

13. The semiconductor device according to claim 10, wherein in cross-sectional view, a distance between the first coil and the fifth coil or a distance between the second coil and the sixth coil is 10 micrometers or more and 14 micrometers or less.

14. The semiconductor device according to claim 10, wherein
the first coil and the fifth coil are overlapped each other in plan view,
the second coil and the sixth coil are overlapped each other in plan view,
the third coil and the seventh coil are overlapped each other in plan view, and
the fourth coil and the eighth coil are overlapped each other in plan view.

15. The semiconductor device according to claim 10, wherein
the first coil and the fifth coil are magnetically coupled to each other,
the second coil and the sixth coil are magnetically coupled to each other,
the third coil and the seventh coil are magnetically coupled to each other, and
the fourth coil and the eighth coil are magnetically coupled to each other.

16. The semiconductor device according to claim 10, wherein
the lead wiring and the fifth electrode pad are connected to a reference potential.
